(19) United States
(12) Patent Application Publication
(10) Pub. No.: US 2025/0290196 A1
(43) Pub. Date: Sep. 18, 2025

(54) ROUTING CHAMBER

(71) Applicant: Applied Materials, Inc., Santa Clara, CA (US)

(72) Inventors: Thomas BREZOCZKY, Los Gatos, CA (US); Kirankumar Neelasandra SAVANDAIAH, Bangalore (IN); Bhaskar PRASAD, Adityapur (IN)

(21) Appl. No.: 18/607,043

(22) Filed: Mar. 15, 2024

(51) Int. Cl. C23C 14/50; C23C 14/02; C23C 14/06; C23C 14/14; C23C 14/56; H02K 41/02; H02N 15/00

(52) U.S. Cl. CPC C23C 14/50; C23C 14/021; C23C 14/0641; C23C 14/14; C23C 14/566; H02K 41/02; H02N 15/00

(57) ABSTRACT

Embodiments of the present disclosure include a chamber. The chamber generally includes a body and a lid assembly configured to be coupled to a top of the body. The lid assembly generally includes a housing including a first magnetic levitation actuator assembly aligned in a first direction, a second magnetic levitation actuator assembly aligned in a second direction, and a plurality of top sensors, where the first direction is different than the second direction. The lid assembly also generally includes a membrane configured to be coupled to the housing, the membrane including a plurality of recesses configured to receive the first magnetic levitation actuator assembly, the second magnetic levitation actuator assembly, and the plurality of top sensors.

### BACKGROUND

### Field

Embodiments described herein generally relate to semiconductor processes and, more particularly, to semiconductor process equipment used in substrate processing systems.

### Description of the Related Art

Semiconductor devices are typically formed on semiconductor substrates using processing systems which include several process chambers, where each process chamber is used to complete one or more of the various steps (e.g., depositions) to form the semiconductor devices (e.g., a memory chip). Processing systems may use substrate transfer systems to move substrates between each of the process chambers. The process chambers and the substrate transfer system of the processing system may each be held at vacuum during processing. Substrate transfer systems may utilize a carrier to move the substrates through and between each of the process chambers. However, precise, reliable, and smooth transportation of the carriers into and out of each of the process chambers may be challenging. For example, it is desirable that processing systems be capable of facilitating the movement and adjustment of the carriers throughout various stages of the processing system. In addition, it is important that processing systems are versatile, including being able to handle common failures during transportation of the carriers. Further, it is important that processing systems (and the movement of the carriers in the processing systems) be adaptable to fulfill a variety of needs.

Accordingly, there exists a need for further improvements in processing systems that include substrate carriers to overcome various challenges above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments provided herein generally include a routing chamber of a substrate processing system configured to accept a substrate carrier.

Embodiments of the present disclosure provide a chamber. The chamber generally includes a body and a lid assembly configured to be coupled to a top of the body. The lid assembly generally includes a housing including a first magnetic levitation actuator assembly aligned in a first direction, a second magnetic levitation actuator assembly aligned in a second direction, and a plurality of top sensors, where the first direction is different than the second direction. The lid assembly also generally includes a membrane configured to be coupled to the housing, the membrane including a plurality of recesses configured to receive the first magnetic levitation actuator assembly, the second magnetic levitation actuator assembly, and the plurality of top sensors.

Embodiments of the present disclosure provide a chamber. The chamber generally includes a body and a lid assembly configured to be coupled to a top of the body. The lid assembly generally includes a housing including a first magnetic levitation actuator assembly aligned in a first direction, a second magnetic levitation actuator assembly aligned in a second direction, a third magnetic levitation actuator assembly aligned in the first direction, a fourth magnetic levitation actuator assembly aligned in the second direction, and a plurality of top sensors, where the first direction is different than the second direction. The lid assembly also generally includes a membrane configured to be coupled to the housing, the membrane including a plurality of recesses configured to receive the first magnetic levitation actuator assembly, the second magnetic levitation actuator assembly, the third magnetic levitation actuator assembly, the fourth magnetic levitation actuator assembly, and the plurality of top sensors. The housing may include a first metal and the membrane may include a second metal different than the first metal.

Embodiments of the present disclosure provide a chamber. The chamber generally includes a body and a lid assembly configured to be coupled to a top of the body. The lid assembly generally includes a housing including a first magnetic levitation actuator assembly aligned in a first direction, a second magnetic levitation actuator assembly aligned in a second direction, a third magnetic levitation actuator assembly aligned in the first direction, a fourth magnetic levitation actuator assembly aligned in the second direction, and a plurality of top sensors. The first direction is different than the second direction, the first magnetic levitation actuator assembly and the third magnetic levitation actuator assembly each include four linear stators, and the second magnetic levitation actuator assembly and the fourth magnetic levitation actuator assembly each include three linear stators. The lid assembly also generally includes membrane configured to be coupled to the housing, the membrane including a plurality of recesses configured to receive the first magnetic levitation actuator assembly, the second magnetic levitation actuator assembly, the third magnetic levitation actuator assembly, the fourth magnetic levitation actuator assembly, and the plurality of top sensors, and where the housing includes aluminum and the membrane includes stainless steel.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a top schematic view of an example substrate processing system, in which embodiments of the present disclosure may be implemented.

FIGS. 2A and 2B illustrate side views of a portion of an example station of the substrate processing system of FIG. 1, in which embodiments of the present disclosure may be implemented.

FIG. 3 illustrates an example carrier that includes a base and magnetic levitation elements, in accordance with embodiments of the present disclosure.

FIG. 4 illustrates a block diagram of an example routing chamber, in accordance with embodiments of the present disclosure.

FIG. 5 illustrates a top view of a system that includes the example carrier of FIG. 3 and the example routing chamber of FIG. 4, in accordance with embodiments of the present disclosure.

FIG. 6 illustrates a side view of the example routing chamber of FIG. 4, in accordance with embodiments of the present disclosure.

FIG. 7A illustrates a housing of a lid assembly of the example routing chamber of FIG. 4, in accordance with embodiments of the present disclosure.

FIG. 7B illustrates a membrane of a lid assembly of the example routing chamber of FIG. 4, in accordance with embodiments of the present disclosure.

FIG. 8 illustrates a view of an example connection between a housing and a membrane of a lid assembly of the example routing chamber of FIG. 4, in accordance with embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to a routing chamber used in a substrate processing system. The routing chamber may include a body, and a lid assembly that include a housing and a membrane each formed from different materials. The lid assembly may include a magnetic levitation assembly that includes a plurality of magnetic levitation actuator assemblies configured to change the axial direction of travel of a carrier (e.g., a semiconductor substrate carrier) used in the substrate processing system. The housing of the lid assembly may be removable and may be configured to support the plurality of magnetic levitation actuator assemblies. The membrane of the lid assembly may be removable and may be configured to be coupled to the housing. The routing chamber may also include various sensors used to measure and/or or detect the presence of and the position of the carrier and/or object(s) being transported by the carrier.

The routing chamber described herein may be included at one or more locations in the substrate processing system, and may enable the movement (including changing the direction of travel) and adjustment of the carriers at various stages throughout the substrate processing system. As a result, the substrate processing system may be more versatile, including being able to handle different types of failures during transportation of the carriers, as well as adaptable to fulfill a wider range of substrate processing system processes and functions. The routing chamber may be able to work in a vacuum or atmospheric pressure environments, allowing the carriers to be transported through a vacuum environment, an atmospheric pressure environment, or sequentially though both environments (in either order).

### Substrate Processing System Example

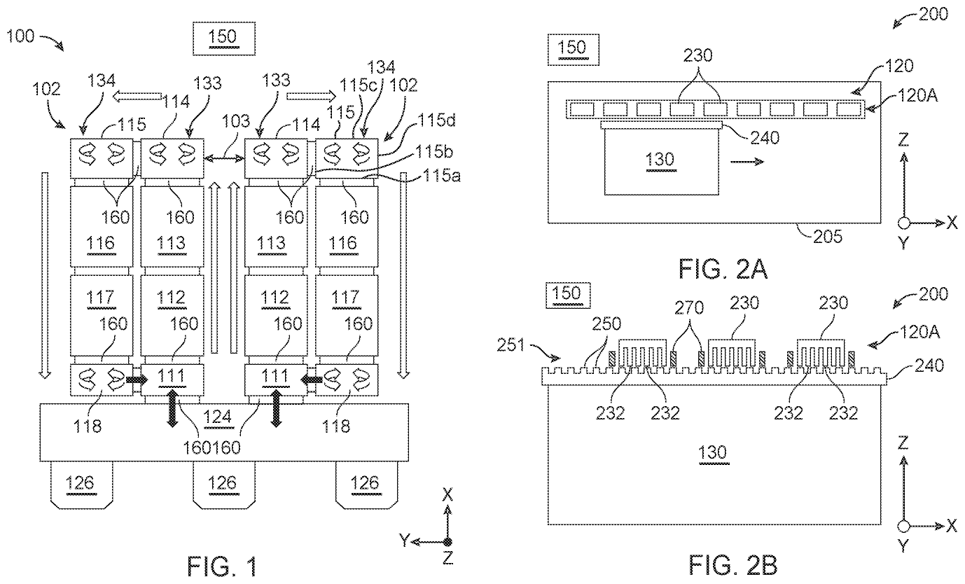

FIG. 1 illustrates a top schematic view of an example substrate processing system 100, in which embodiments of the present disclosure may be implemented. The substrate processing system 100 includes a controller 150 and one or more processing lines 102.

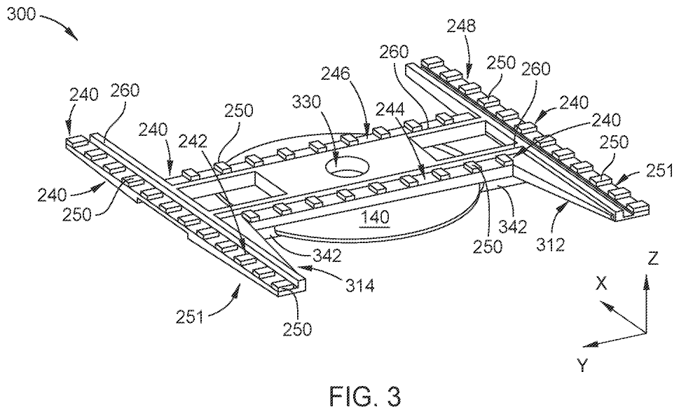

The one or more processing lines 102 each include a plurality of stations, as illustrated in FIG. 1. In one example, the processing line 102 illustrated on the right side of FIG. 1 includes at least four processing stations 112, 113, 116 and 117, the processing line 102 illustrated on the left side of FIG. 1 includes at least four processing stations 112, 113, 116 and 117. However, processing stations 111, 114, and 115 may also be configured to perform one or more substrate processing processes. Each processing line 102 may include a magnetic transportation system (not shown) that includes a plurality of individual magnetic levitation assemblies disposed within the stations 111-118 that are configured to convey an object 140 (FIG. 3) disposed on a carrier 130 (FIGS. 2A-2B and 3) through the processing line 102. Each processing line 102 may be independent of other processing lines 102. The processing lines 102 may be physically separated by one another by a gap 103. The gap 103 may be sized such that a technician may walk between each processing line 102 to service the one or more stations 111-118.

Each processing line 102 may include a plurality of slit valves 160 to selectively isolate each station 111-118. The slit valves 160 may be selectively opened and closed to allow a clear path for the travel of the carrier 130, to selectively isolate the stations 111-118 from one another, and to facilitate the pressurization or depressurization of the stations 111-118.

The substrate processing system 100 may be used to process multiple substrates in each processing line 102 to produce a desired fabricated substrate. In some cases, the substrate processing system 100 may include a plurality of physical vapor deposition (PVD) processing chambers. For example, the first station 111 may be a first load lock station, the second station 112 may be a degas station, the third station 113 may be a pre-clean station, the fourth station 114 may be a routing station, the fifth station 115 may be a routing station, the sixth station 116 may be a PVD tantalum nitride deposition station, the seventh station 117 may be a PVD copper deposition station, and the eighth station 118 may be a routing station that also serves as a buffer station. An object 140 (e.g., substrate) may be transferred and processed within each process station 112-113 and 116-117. The magnitude of a vacuum within each station 111-118 may increase from station to station. For example, the magnitude of the vacuum in the seventh station 117 may exceed the magnitude of a vacuum in the other stations (e.g., stations 111-116 and 118).

The first station 111 (e.g., load lock station) may have a magnetic levitation assembly 120, which includes one or more magnetic levitation actuator assemblies 120A that include a plurality of linear stators 230 (FIG. 2B) and optionally a plurality of top sensors 270. As will be discussed further below, the stations 111-118 each typically include two or more magnetic levitation actuator assemblies 120A that are spaced apart within each of the stations 111-118 to support the carrier 130 as the carrier 130 is transferred through the station. The stations 112-113 and 116-117 (e.g., process stations) may each have a magnetic levitation assembly 120. The fourth station 114, fifth station 115, and eighth station 118 (e.g., routing stations) may each have a magnetic levitation assembly 120. The routing stations may each have four sidewalls 115a, 115b, 115c, 115d, as illustrated. The fifth station 115 may also include a plurality of shutter disks to be placed on a carrier 130 without the object 140. The shutter disks are used to receive deposition material when needed in the place of the object 140 to clean processing equipment, such as cleaning buildup found on a PVD target disposed within the PVD deposition process stations (e.g., stations 116-117).

The magnetic levitation assembly 120 of the first station 111 and the magnetic levitation assembly 120 of the eighth station 118 may cooperate to change the transfer direction (e.g., X-direction to Y-direction) of the carrier 130 within the substrate processing system 100. Additionally, the magnetic levitation assembly 120 of the fourth station 114 and the magnetic levitation assembly 120 of the fifth station 115 may cooperate to change the transfer direction of travel of the carrier 130.

FIGS. 1, 2A, 2B, 3, 4, 5, and 6 include an X-Y-Z coordinate system to illustrate the transfer directions of the carrier 130 and object 140 through the substrate processing system 100, as well as the orientation of the carrier (e.g., carrier 130, 300). The arrows illustrate the direction that one or more carriers 130 circulate within the processing line 102. During an example processing operation, the carrier 130 receives an object 140 entering the first station 111 in the X-direction from one or more front opening unified pods (FOUPS) 126 of a factory interface 124. The carrier 130 is then conveyed to the second station 112 in the X-direction. The first station 111 also receives the carrier 130 from the eighth station 118 in the Y-direction. After the carrier 130 is conveyed into the second station 112, the carrier 130 is conveyed to the fourth station 114 through the third station 113 in the X-direction. The carrier 130 is then conveyed from the fourth station 114 to the fifth station 115 in the Y-direction. The carrier 130 is then conveyed from the fifth station 115 to the eighth station 118 in the negative X-direction through the stations 116-117. The carrier 130 is then conveyed in the Y-direction back into the first station 111. The now fabricated object 140 is transferred back to the FOUP 126. Another object 140 may then be placed onto the carrier 130 in the first station 111 for another processing operation. A shutter disk may be conveyed on a carrier 130 from the fifth station 115 to the first station 111 in a similar manner as the object 140.

In some embodiments of the substrate processing system 100, the processing line 102 has a non-deposition portion 133 and a deposition portion 134. The non-deposition portion 133 may include a linear arrangement of stations, such as the first station 111, the second station 112, the third station 113, and the fourth station 114, that do not subject the object 140 to a process that deposits a layer on the object 140. After the object 140 passes through the non-deposition portion 133, the object 140 is conveyed into the deposition portion 134 that may be a linear arrangement of stations, such as the fifth station 115, the sixth station 116, the seventh station 117, and the eight station 118, that includes at least one station that deposits at least one layer the object. For example, the non-deposition portion 133 includes the first station 111 that is a first load lock, the second station 112 that is a degas station, the third station 113 that is a pre-clean station, and the fourth station 114 that is a routing station. The deposition portion 134 includes the fifth station 115 that is a routing station, the sixth station 116 that is a tantalum nitride deposition station, the seventh station 117 that is a copper deposition station, and the eighth station 118 that is a routing station that also serves as a buffer station.

FIGS. 2A and 2B illustrate side views of a portion 200 of an example process station (e.g., stations 112-113 and 116-117) of the substrate processing system 100 of FIG. 1, in which embodiments of the present disclosure may be implemented. The example process station, which may be the process station 112-113, 116-117 described above, may be referred to herein as simply the process station 205 for clarity. The process station 205 may be configured for contactless transportation of the carrier 130. The process station 205 may include a processing chamber that is maintained at a vacuum pressure, such that the processing region of the chamber is at a pressure that is less than 760 Torr, or even at a pressure between 1 milliTorr (mTorr) and 500 Torr. The process station 205 may be configured for contactless transportation of the carrier 130 in a vacuum chamber disposed below the processing chamber, or also referred to herein as a processing station.

The carrier 130 may be configured to carry one or more objects 140. For example, the carrier 130 may be a substrate carrier, a shutter disk carrier or a mask carrier. The carrier 130 may also be configured to transport process kit component parts. The carrier 130 may be transported in the X-direction or negative X-direction, as illustrated in FIG. 2A. The carrier 130 may also be transported in the Y-direction or negative Y-direction, as described above. In some cases, the object may be carried below the carrier 130 during transport, as illustrated in FIG. 3.

The carrier 130 includes one or more a magnetic levitation elements 240 that allow the carrier 130 to be levitated and transported through the process station 205. Each magnetic levitation element 240 may be a track in the X-direction or the Y-direction. The magnetic levitation element 240 may be a substantially straight magnetic levitation element 240, or may at least include one or more straight portions that allow the carrier 130 to be contactlessly transported through the substrate processing system 100. The magnetic levitation element 240 may define a transportation direction (or transport direction), along which the carrier 130 is contactlessly transported. In one example, and as illustrated in FIG. 2A, the carrier 130, which includes one or more magnetic levitation elements 240, is transferred through the process station 205, and to and from other adjacent process stations 205 (not shown), by magnetic levitation, without the carrier 130 contacting the walls or components within the processing station 205.

As illustrated in FIG. 2A, the process station 205 includes a magnetic levitation assembly 120 that includes a plurality of magnetic levitation actuator assemblies 120A. The magnetic levitation actuator assemblies 120A each includes a plurality of linear stators 230. For example, a magnetic levitation actuator assembly 120A may include two or more, three or more, five or more, or 10 or more linear stators 230, depending on the desired length of the magnetic levitation element 240, which is often referred to herein as a magnetic levitation element 240. Alternatively, the magnetic levitation actuator assemblies 120A of the magnetic levitation assembly 120 may include one elongated linear stator 230 extending along the entire length of a magnetic levitation element 240. The number of linear stators 230 shown in FIGS. 2A and 2B are examples, and a greater or lesser number of linear stators 230 may be used.

The linear stator 230 may be arranged to guide a corresponding magnetic levitation element 240 of the carrier 130, which is disposed underneath the linear stator 230. For example, a plurality of linear stators 230 may be disposed one after the other in a row, such as shown in FIG. 2A, extending in the X and/or Y-direction. The one or more linear stators 230 may be configured to remain stationary during contactless transportation of the carrier 130 along the magnetic levitation element 240 since the one or more linear stators 230 are coupled to a wall (e.g., top wall or side wall) of the process station 205.

The one or more linear stators 230 may include a plurality of stator poles 232, such as 2, 4, 6, 8 or more stator poles 232, as illustrated in FIG. 2B. The number of stator poles 232 shown in FIGS. 2A and 2B are examples, and a greater or lesser number of stator poles 232 may be used. The stator poles 232 may be protrusions, or teeth, that may project towards the carrier 130 and/or towards a magnetic levitation element 240 attached to the carrier 130. The plurality of stator poles 232 may define at least one comb structure. In some embodiments, a linear stator 230 may include two comb structures, each having a plurality of stator poles 232.

The magnetic levitation assembly 120, which includes the one or more linear stators 230, and the stator poles 232, may include, or be made of, a magnetic material, more specifically a ferromagnetic material. The magnetic material may be a non-permanent, or soft, magnetic material. The magnetic material may be a metal, such as electrical steel, silicon steel, ferritic steel, martensitic steel, or any other soft magnetic material.

The magnetic levitation element(s) 240 of the carrier 130 may include, or be made of, a magnetic material, such as a ferromagnetic material. The magnetic material may be a non-permanent, or soft, magnetic material. The magnetic material may be a metal, such as electrical steel, silicon steel, ferritic steel, martensitic steel, or any other soft magnetic material.

In some embodiments, as shown in FIG. 2A, the carrier 130 may be levitated and contactlessly transported in the X or Y-direction through the substrate processing system 100, for example when the carrier 130 is a substrate carrier for a large area substrate or a mask carrier carrying a mask for a large area substrate. The magnetic levitation element 240 is coupled to a portion of the top of the carrier 130, as illustrated. The magnetic levitation assembly 120, or at least a portion thereof, may be disposed above the carrier 130.

The carrier 130 is configured to be levitated and transported along the length of the magnetic levitation assembly 120 by use of the one or more linear stators 230 of the magnetic levitation assembly 120 that remain stationary within the process station 205. During contactless levitation and/or transportation of the carrier 130, the magnetic levitation element 240 faces at least one linear stator 230. The magnetic levitation element 240 may respectively face different linear stators 230 as the carrier 130 is transported along the magnetic levitation element 240.

The magnetic levitation element 240 may include an array of features 250. Any number of features 250 may be formed within an array of features 251. The features 250 may be protrusions, or teeth, that may project towards at least one linear stator 230 of the opposing magnetic levitation actuator assembly 120A. The raised segments of features 250, which include a magnetic material, may define a comb-like structure as illustrated in FIGS. 2B and 3. Each magnetic levitation element 240 may also include a featureless portion 260 adjacent to each array of features 250. The featureless portion 260 may span the same or part of the length of the array of features 251. The featureless portion 260 may be substantially flat (e.g., a flat surface) such that the top sensors 270 may be used to measure and/or or detect a position of the carrier 130 during contactless levitation and/or transportation. In some embodiments, the featureless portion 260 may not be included in the carrier 130, and another portion of the carrier 130 may be to enable the sensors 270 to measure and/or or detect a position of the carrier 130. The featureless portion 260 may also be implemented by a planar surface or a non-planar surface. The featureless portion 260 may also have features of the same or varying heights.

A pitch, or spacing, may be provided between adjacent stator poles 232 of a linear stator 230. The term “adjacent stator poles” (and likewise “adjacent features 250”) refers to poles of a same linear stator 230 that are adjacent to each other with respect to the direction defined by the magnetic levitation element 240, such as the transportation direction (e.g., X-direction in FIG. 2A). The pitch may be a distance, e.g. a horizontal distance, extending along the magnetic levitation element 240. Likewise, a pitch or spacing may be provided between adjacent features 250 of the magnetic levitation element 240. According to some embodiments, a first pitch between adjacent stator poles 232 of a linear stator 230 may be different from a second pitch between adjacent features 250 of the magnetic levitation element 240. Particularly, a ratio of the first pitch and the second pitch may be non-integer (the first pitch is not an integer multiple of the second pitch and the second pitch is not an integer multiple of the first pitch). The stator poles 232 of the linear stator 230 and the features 250 of the magnetic levitation element 240 may be provided according to a p/q configuration. A p/q configuration means that the distance (in the transportation direction) spanned by p consecutive adjacent stator poles 232 of the linear stator 230 includes a total of q features 250 of the magnetic levitation element 240. In some embodiments, q may be equal to p+1 or to p−1. For example, it may be the case that p=3 and q=2; or p=3 and q=4. In further examples, it may be the case that p=4 and q=3.

According to some embodiments, the one or more linear stators 230 of the magnetic levitation assembly 120 include a set of electromagnets. In light thereof, the one or more linear stators 230 are active magnetic systems that can provide an adjustable, controllable magnetic field. For example, each stator pole 232 of the linear stator 230 may include an electromagnet. The electromagnet may include a respective coil wound around each stator pole 232. Different winding schemes for winding the coils around each stator pole 232 may be provided. For example, the coils may be wound vertically, in that the coils are wound from top to bottom (clockwise) or from bottom to top (counter-clockwise). In some embodiments, the magnetic levitation element 240 may not include an electromagnet. The magnetic levitation element 240 may be a magnetically passive system, where the magnetic levitation element 240 is formed from a ferromagnetic material, without any electromagnets mounted thereon. In some embodiments, the magnetic levitation element 240, or at least the features 250 formed thereon, include a ferromagnetic material such as a material selected from a group comprising transition metals (e.g., iron, nickel, cobalt) and their alloys, and alloys of rare-earth metals. In one example, the magnetic levitation element 240 includes a ferritic stainless steel, such as a 409, 430 and 439 stainless steel. The magnetic levitation element 240 may also include an electrical steel, silicon steel, martensitic steel, or any other soft magnetic material.

In some embodiments, the magnetic levitation assembly 120 includes two parallel magnetic levitation actuator assemblies 120A running in the X-direction configured to levitate carrier 130 and convey the carrier 130 in either the positive or negative X-direction. The carrier 130 similarly includes two parallel magnetic levitation elements 240 running in the X-direction. Each magnetic levitation element 240 is positioned on the carrier 130 to be directly underneath the one or more linear stators 230 of a respective magnetic levitation actuator assembly 120A running in the X-direction when the carrier is being conveyed in the X-direction. Additionally, the magnetic levitation assembly 120 may also include two parallel magnetic levitation actuator assemblies 120A running in the Y-direction configured to levitate the carrier 130 and convey the carrier 130 in either the positive or negative Y-direction. The carrier 130 similarly includes two parallel magnetic levitation elements 240 running in the Y-direction. Each magnetic levitation element 240 is positioned on the carrier 130 to be directly underneath the one or more linear stators 230 of a respective magnetic levitation actuator assembly 120A running in the Y-direction when the carrier 130 is being conveyed in the Y-direction. As the carrier 130 moves in the Y-direction, the magnetic levitation elements 240 running in X-direction move out of alignment with the corresponding magnetic levitation actuator assemblies 120A running in the X-direction. The magnetic levitation actuator assemblies 120A running in the Y-direction are able to maintain levitation as the carrier 130 is moved in the Y-direction. The carrier 130 may be conveyed in the Y-direction to another station (e.g., from the fourth station 114 to the fifth station 115) until the magnetic levitation elements 240 running in the X-direction become aligned with corresponding magnetic levitation actuator assemblies 120A running in the X-direction where the carrier 130 may then be conveyed again in the X-direction.

The process station 205 may include the controller 150. The controller 150 may be connected to the set of electromagnets of the linear stators 230 for controlling a current in the electromagnets. The current can be increased to increase the attraction force of the set of electromagnets to raise the carrier 130 or decreased to lessen the attraction force of the set of the electromagnets to lower the carrier 130.

The controller 150 as described herein may be a single centralized controller or may be a distributed controller including a plurality of individual control units. The controller 150 may include a central processing unit (CPU), a memory and, for example, support circuits. To facilitate control of the carrier 130, the CPU may be one of any form of general-purpose computer processor that can be used in an industrial setting for controlling various components and sub-processors. The memory may be coupled to the CPU. The memory, or a computer readable medium, may be one or more readily available memory devices such as random-access memory, read only memory, a floppy disk, a hard disk, or any other form of digital storage either local or remote. The support circuits may be coupled to the CPU for supporting the processor in a conventional manner. The circuits in question include cache, power supplies, clock circuits, input/output circuitry and related subsystems, and the like.

The one or more linear stators 230 including the electromagnets may, together with the magnetic levitation element 240, form a linear reluctance motor for providing both a contactless levitation and a contactless drive of the carrier 130. A linear reluctance motor is configured for providing a linear motion, or translational motion, of the carrier 130. A linear motor is distinguished from a rotary motor, which provides a rotational motion. The linear reluctance motor of the apparatus according to embodiments described herein provides a linear motion of the carrier 130 along the magnetic levitation assembly 120.

The process station 205 may include one or more top sensors 270 for measuring or detecting a position of the carrier 130 during contactless levitation and/or transportation. Although the one or more top sensors 270 are illustrated herein as being included on a top of the process station 205, in some embodiments, the one or more top sensors 270 may be included in a bottom of the process station 205. For example, top sensors 270 may be provided on opposite ends of each linear stator 230. Each top sensor 270 may be configured to detect the presence of the carrier 130. Each top sensor 270 may also be configured to measure a position of the carrier 130, which may include a vertical position and/or a horizontal position of the carrier 130, for example a horizontal position with respect to the transportation direction. The top sensors 270 may be Hall effect based sensors, optical sensors, ultrasonic sensors, capacitive sensors, Eddy current sensors, magnetic sensors, and the like. Each top sensor 270 may be connected to the controller 150. The top sensors 270 may also be configured to determine the presence of and/or size of an object 140 (FIG. 3) being transported by the carrier 130. The top sensors 270 may be high-precision sensors that have a sensor resolution of 100 μm or less, particularly 10 μm or less. Accordingly, the carrier 130 may be positioned vertically and/or horizontally in a target position with high precision. In some embodiments, the top sensors 270 are included in the magnetic levitation assemblies 120.

The process station 205 according to embodiments described herein may include one or more top sensors 270 for detecting a position of the carrier 130 with respect to a transportation direction of the carrier 130. The controller 150 may be configured to control the reluctance-based drive force in response to a signal provided by the one or more top sensors 270 to position the carrier 130 in a target position with respect to the transportation direction. The reluctance-based drive force may be configured to align the carrier 130 along the magnetic levitation element 240 or transport direction. By controlling amplitude and phase angle of an AC signal provided to the coils coupled to the stator poles 232, the dynamic motion characteristics of the magnetic levitation elements 240 and thus the carrier 130, such as the amount of jerk, acceleration, velocity, and finally horizontal position can be adjusted and achieved.

In some embodiments, the substrate processing system 100 may include processing areas (e.g., areas not subject to vacuum) in the factory interface 124, and the carrier 130 may be configured to be transported through the processing areas. For example, the carrier 130 may be loaded onto the magnetic levitation assembly 120 and enter the substrate processing system 100 and be inspected in a processing area (not shown) subject to normal atmosphere before entering a load lock station (e.g., first station 111). In this manner, the magnetic levitation assembly 120 may precede the processing area and be external to the substrate processing system 100.

### Carrier Configuration Example

FIG. 3 illustrates an example carrier 300 that includes the magnetic levitation element(s) 240 of FIGS. 2A and 2B, in accordance with embodiments of the present disclosure. In some embodiments, the carrier 130 described above may be implemented as the carrier 300. The carrier 300 of FIG. 3 may be similar to the carrier 130 of FIGS. 2A-2B, and everything discussed herein with respect to the carrier 130 may also apply to the carrier 300.

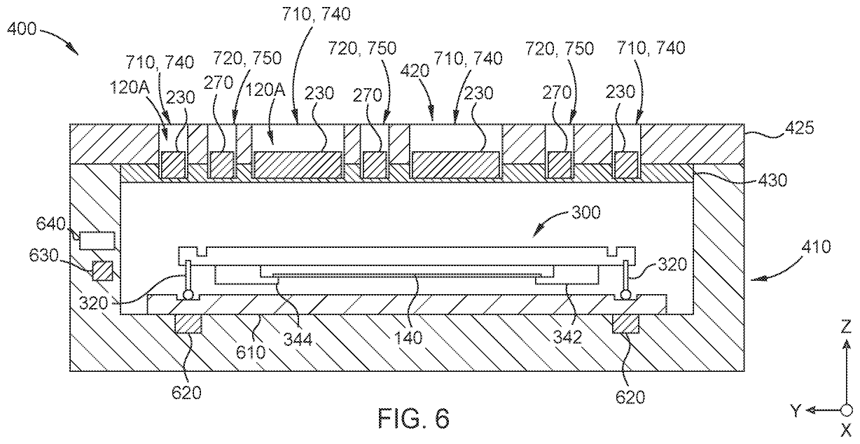

The carrier 300 may include an array of legs 320 (not shown in FIG. 3, but illustrated in FIG. 6) disposed below and/or coupled to the magnetic levitation element(s) 240. The carrier 300 may further include one or more substrate support members 342 and 344 (not shown in FIG. 3, but illustrated in FIG. 6) coupled to the magnetic levitation element(s) 240. Although the object 140 is illustrated in FIG. 3 as a substrate, the carrier 300 may also be configured to carry other objects. For example, the carrier may be configured to carry a mask, shutter, process kits parts, or other objects used in semiconductor processing, as described above. The carrier 130 may also be configured to transport shutter or process kits parts.

The magnetic levitation element(s) 240 of the carrier 300 may be configured to be associated with an Eigen frequency of at least 200 hertz (Hz), which relates to the inductance associated with the interaction of the magnetic fields generated by the coils within the linear stators 230 and a magnetic levitation element 240. An Eigen frequency of at least 200 Hz may enable the controller 150 of the process station 205 to more easily control the levitation and transportation of the carrier 300 and the object 140. For example, the thickness of at least a portion of the magnetic levitation element(s) 240 in the center of the carrier 300 may be at least 15-20 mm to enable the carrier 300 to have an Eigen frequency of at least 200 Hz. In some embodiments, the carrier 300A may be made out of high strength low mass materials (e.g., titanium, inconel), which may enable the thickness of at least a portion of the magnetic levitation element 240 together with the base 310 in the center of the carrier 300A to be less than 15-20 mm. The mass of the carrier 300A will affect the Eigen frequency of the carrier 300A.

In some embodiments, the magnetic levitation element(s) 240 may include or be implemented as one or more rails (e.g., rails 242, 244, 246, 248). In some cases, the magnetic levitation element(s) 240 of the carrier 300 may include a first rail 242 aligned in a first direction (e.g., the X-direction). The magnetic levitation element(s) 240 may also include a second rail 244 aligned in a second direction (e.g., the Y-direction). The magnetic levitation element(s) 240 may also include a third rail 246 aligned in the Y-direction and is aligned parallel to the second rail 244. The magnetic levitation element(s) 240 may also include a fourth rail 248 aligned in the X-direction, and may be aligned parallel to the first rail 242. Although the carrier 300 in FIG. 3 is illustrated as having four rails 242, 244, 246, 248, any number of rails may be used in the carrier 300. In some cases, the carrier 300 may include just the first rail 242 aligned in the X-direction and the second rail 244 aligned in the Y-direction. In some embodiments, the second rail 244 and the third rail 246 may be considered and/or implemented as a single rail.

The dimensions of the carrier 300 (including the rails 242, 244, 246, 248) may be based on at least one of the size of the stations 111-118, the location of the top sensors 270 in the stations 111-118, or the size of the objects (e.g., the object 140) being transported by the carrier 300. The dimensions of the carrier 300 may also be selected to facilitate the stability of the carrier 300 during transportation of the object(s) 140, as well as ensure the stability of the carrier 300 when nothing is transported. The carrier 300 may also be configured to be large enough to support the object(s) 140 and small enough to pass into, through, and out of stations (e.g., stations 111-118) of a substrate processing system (e.g., substrate processing system 100), as described above. In some cases, a ratio of a length of the carrier 300 to a length of an object (e.g., object 140) may be between 1:1 and 2:1. In some cases, the ratio of the length of the carrier 300A to the length of the object 140 may be 3:2. For example, a ratio of a length of the first rail 242 or the fourth rail 248 to a length of the object 140 may be between 1:1 and 2:1.

The features 250 of the magnetic levitation element(s) 240 may be arranged on the rails 242, 244, 246, 248. In some embodiments, a pitch and/or spacing may be provided between adjacent features 250, as described above. The features 250 may also be arrange side by side. As illustrated in FIG. 3, the array of features 250 of the first rail 242 may be aligned in the X-direction along a surface of the first rail 242, the array of features 250 of the second rail 244 may be aligned in the Y-direction along a surface of the second rail 244, the array of features 250 of the third rail 246 may be aligned in the Y-direction along a surface of the third rail 246, and the array of features 250 of the fourth rail 248 may be aligned in the X-direction along a surface of the fourth rail 248. In some embodiments, the features 250 may be arranged linearly. A gap between each feature may vary between features 250, or may be the same along the rails 242, 244, 246, 248.

In some embodiments, the features 250 of the rails 242, 244, 246, 248 may cover a portion of the top of the carrier 130. Another featureless portion 260 of the magnetic levitation elements 240 may not include the features 250. In other words, the featureless portion 260 of the top of the carrier may not include the features 250 and thus be positioned adjacent to a portion of the magnetic levitation element(s) 240 that includes the features 250. The featureless portion 260 may be substantially flat (e.g., a flat surface), and configured to enable the top sensors 270 to measure and/or or detect a position of the carrier 130 during contactless levitation and/or transportation, as described above. In some embodiments, the top sensors 270 may be positioned above the carrier 130 to measure and/or or detect a position of the carrier 130 during contactless levitation and/or transportation, as illustrated in FIG. 6, as described below. The featureless portion 260 may be included on the top of one or more of the rails 242, 244, 246, 248 of the carrier 300, and may be implemented as a featureless track that is aligned with the array of features 250. In some embodiments, the magnetic levitation elements 240 may each include an outer portion and an inner portion. In these embodiments, the features 250 may be located on one or more outer portions of the magnetic levitation element(s) 240 and the featureless portion 260 may be located on one or more inner portions of the magnetic levitation elements 240, as illustrated in FIG. 3.

During transportation, portions of the object 140 (e.g., the leading and trailing edges of the object 140) may be uncovered by the carrier 130 (e.g., as illustrated in FIG. 3), to assist in the enablement of the top sensors 270 to sense the presence and/or position of the object 140. In addition, the exposed leading and trailing edges of the object 140 may enable the top sensors 270 to determine the dimensions of the object 140. In some embodiments, one or more of the sensors 270 may be a drive sensor, and the carrier 130 may include a leading edge trigger (not illustrated), configured to interact with the drive sensor to alert the substrate processing system 100 of an incoming carrier. For example, the leading edge trigger may be a permanent magnet configured to trigger the drive sensor of the sensors 270 to let the substrate processing system 100 detect the leading edge of the carrier 130. The permanent magnet may be positioned in one or more of the legs 320 of the carrier 130.

As briefly discussed above, the rails 242, 244, 246, 248 may be spaced apart from each other, as illustrated in FIG. 3. In some cases, the first rail 242 may be spaced a distance in the Y-direction from the fourth rail 248. In some cases, the second rail 244 may be spaced a distance in the X-direction from the third rail 246. In some embodiments, the carrier 130 may have a substantially symmetric shape. That is, the distance from a first end of the first rail 242 to a center of the carrier 130 may be substantially the same as the distance E from a second end of the first rail 242 (e.g., the second end being opposite to the first end) to the center of the carrier 130. For example, the carrier 300 may include the first rail 242 aligned in the X-direction, the second rail 244 aligned in the Y-direction, and the fourth rail 248 aligned in the X-direction, and the second rail 244 may have a center line extending in the Y-direction. In this example, a distance between first ends of the first rail 242 and the fourth rail 248 and the center line is substantially the same as a distance between second ends (e.g., the second ends being opposite to the first ends) of the first rail 242 and the fourth rail 248 and the center line. The stations 111-118 of the substrate processing system 100 may be configured to permit a symmetric carrier (e.g., carrier 300) to remain in the processing station 205 during processing, without impacting processing in the processing station. For example, the processing station 205 may be large enough to accommodate the carrier 300 positioned on an end of the processing station 205 while the object 140 undergoes processing, such that the carrier 300 does not impact the processing.

In some embodiments, the carrier 300 may have an asymmetric shape. That is, the distance from a first end of the first rail 242 to the center of the carrier 130 may be different than the distance E from a second end of the first rail 242 (e.g., the second end being opposite to the first end) to the center of the carrier 130 . . . . For example, the carrier 300 may include the first rail 242 aligned in the X-direction, the second rail 244 aligned in the Y-direction, and the fourth rail 248 aligned in the X-direction, and the second rail 244 may have a center line extending in the Y-direction. In this example, a distance between first ends of the first rail 242 and the fourth rail 248 and the center line is different than a distance between second ends (e.g., the second ends being opposite to the first ends) of the first rail 242 and the fourth rail 248 and the center line. When the carrier is asymmetric, the stations 111-118 of the substrate processing system 100 may be able to be smaller than when the carrier is symmetric, as an asymmetric carrier is able to more easily remain in the processing station 205 during processing without impacting the processing.

In some embodiments, it is beneficial to select the material from which the carrier 300 is made to include a material that can also withstand high processing temperatures. In one example, the carrier 300 is made from a ceramic material (e.g., alumina, quartz, zirconia, etc.). In some cases, the carrier 300 may be coated with an electrically conductive coating to resolve any charge build-up issues in the substrate carrier 300 during processing within the process station 205. In some embodiments, the rails 242, 244, 246, 248 may include a magnetic material, such as a ferromagnetic material as described above.

The carrier 300 may be configured such that a center of gravity of the carrier 300 is within 5 millimeters (mm) of a geometric center of the carrier 300, regardless of whether the carrier 300 is currently transporting an object 140. This helps to ensure the stability of the carrier 300. In some embodiments, magnetic levitation element(s) 240 may include at least one at least one extending feature (e.g., extending features 312, 314), as illustrated in FIG. 3. In some cases, the extending features 312, 314 may be configured to ensure that the center of gravity of the carrier 300 is within 5 mm of a geometric center of the carrier 300, regardless of whether the carrier 300 is currently transporting the object 140. The extending features 312, 314 may include, or be made of, metal or ceramic.

The array of legs 320 (e.g., pegs) (illustrated in FIG. 6) may be included in the carrier 300 and may be configured to support the carrier 300. The legs 320 may be coupled to or disposed under the magnetic levitation element(s) 240 of the carrier 300. The array of legs 320 may include any number of legs 320, such as an even number of legs 320. The legs 320 may be electrically coupled to one or more of the rails 242, 244, 246, 248, and may be configured to electrically ground the carrier 300 (e.g., through contact between the carrier 300 and the membrane 430, or through contact between the carrier 300 and another feature of the routing chamber 400). One or more of the rails 242, 244, 246, 248 may be positioned over the over the array of legs 320. In some embodiments, each rail 242, 244, 246, 248 may include at least four legs 320. In other embodiments, the array of legs 320 may be disposed only under the rails 242 248, or the rails 244 and 246. In some embodiments, the legs 320 disposed under one or more of the rails 242, 244, 246, 248 may be implemented as a continuous solid bar or structure. For example, when the array of legs is disposed only under the rails 242, 248, the array of legs 320 under each of the rails 242, 248 may be implemented as a continuous solid bar or structure instead of discrete legs.

The carrier 300 may also include the opening 330 in one or more of the magnetic levitation element(s) 240, as illustrated. The opening 330 may be configured to enable a top sensor (e.g., top sensors 270) to sense the presence and/or position of the object 140.

The support members 342, 344 of the carrier 300 may extend into a region below the carrier 300. The support members 342, 344 may be configured to support the object 140. In some embodiments, the support members 342, 344 may be made of a ceramic or a material that is different from the material of the magnetic levitation element(s) 240. The support member 342 may form a gap of 230 mm between the support member 342 and the support member 344, the gap configured to be small enough that the object 140 may rest on a portion of the support members 342, 344. The object 140 may be supported below the carrier 300. In some embodiments, the support members 342, 344 may be implemented by a single blade coupled to one side of the base 310 that extends into a region below the carrier, and may be is configured to support the object 140.

In some embodiments, the carrier 300 may include additional support members (not shown) configured to support more than one object. For example, the carrier 300 may be configured to carry two or more objects 140 simultaneously. In this example, the carrier 300 may include a third support member and a fourth support member both configured to support an object 140.

### Routing Chamber Example

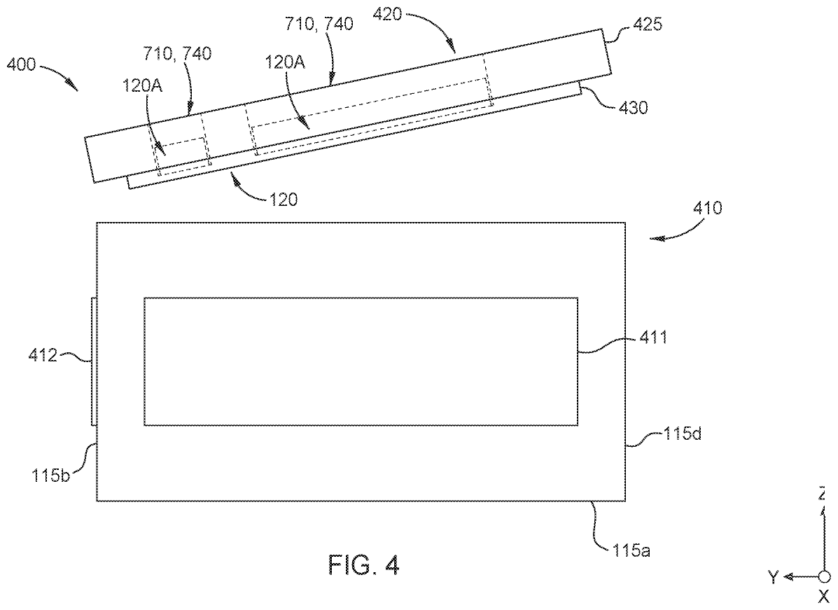

FIG. 4 illustrates a block diagram of an example routing chamber 400, in accordance with embodiments of the present disclosure. The routing chamber 400 may be utilized in a substrate processing system (e.g., substrate processing system 100). For example, the fourth station 114, fifth station 115, and eighth station 118 (e.g., routing stations) of the substrate processing system 100 may be implemented as the routing chamber 400.

The routing chamber 400 includes a body 410 and a lid assembly 420 configured to be coupled to a top of the body 410. The lid assembly 420 may be configured to be coupled to the body 410 such that the interior of the body 410 is sealed and isolated from the outside world. The lid assembly 420 includes a housing 425 and a membrane 430. The membrane 430 may be configured to be coupled to the housing 425. The housing 425 may be formed of a first material, and the membrane 430 may be formed of a second material that is different than the first material. In some embodiments, the first material and the second material may be metals. For example, the housing 425 may be formed of a first material that may be or include aluminum, and the membrane 430 may be formed of a second material that may be or include stainless steel. The thickness of the membrane 430 may be between 0.1 mm to 10 mm, such as 0.5 mm to 3 mm. In some embodiments, the thickness of the membrane 430 may be between 0.1 mm and 2 mm when the membrane 430 is formed of metallic materials (e.g., SST 300 series or titanium). In other embodiments, the thickness of the membrane 430 may be between 0.1 mm and 5 mm for non-metallic materials (e.g., ceramic, including, for example, alumina, aluminum nitride, and zirconium dioxide).

The lid assembly 420 of the routing chamber 400 may be configured to include a magnetic levitation assembly (e.g., magnetic levitation assembly 120), which includes one or more magnetic levitation actuator assemblies (e.g., magnetic levitation actuator assemblies 120A), as described above. In some embodiments, and as described above, the lid assembly 420 may include a plurality of openings 710 configured to include one or more magnetic levitation actuator assemblies 120A running in the X-direction configured to levitate the carrier 300 and convey the carrier 300 in either the positive or negative X-direction, and one or more magnetic levitation actuator assemblies 120A running in the Y-direction configured to levitate the carrier 300 and convey the carrier 300 in either the positive or negative Y-direction. In some cases, the one or more magnetic levitation actuator assemblies 120A may be disposed in the openings 710 and be supported by the housing 425. The membrane 430 may include a plurality of recesses 740 configured to receive the one or more magnetic levitation actuator assemblies 120A. In this manner, the one or more magnetic levitation actuator assemblies 120A may be supported by the housing 425, and may be configured to extend through the recesses 740 of the membrane 430 and into the body 410. As such, the housing 425 may be configured to support the weight of the magnetic levitation actuator assemblies 120A without the help of the membrane 430.

The body 410 of the routing chamber 400 may include four sidewalls (sidewalls 115a, 115b, 115c, 115d). In some embodiments, a port may be included in one or more of the four sidewalls 115a, 115b, 115c, 115d. For example, a first port 411 may be included in the first sidewall 115a of the body 410, and a second port 412 may be included in the second sidewall 115b of the body, as illustrated. In this example, the first sidewall 115a is adjacent to and perpendicular to the second sidewall 115b. Although the first sidewall 115a and the second sidewall 115b are illustrated in FIG. 4 with a port, any combination of the sidewalls 115a, 115b, 115c, 115d may include a port. The ports 411, 412 may be configured to accept a carrier (e.g., carrier 300). In some cases, a port may be included in a bottom of the body 410, and the port may be configured to enable cooling or heating the routing chamber 400.

The housing 425 and the membrane 430 of the lid assembly 420 may be removable from the routing chamber 400, and the housing 425 may be removable from the membrane 430, as illustrated in FIG. 4. In this manner, the housing 425 and the membrane 430 may be serviced and/or cleaned separately from one another, and separately from the body 410. The housing 425 and the membrane 430 may be configured to isolate the magnetic levitation actuator assemblies 120A and the top sensors 270 from the interior of the body 410.

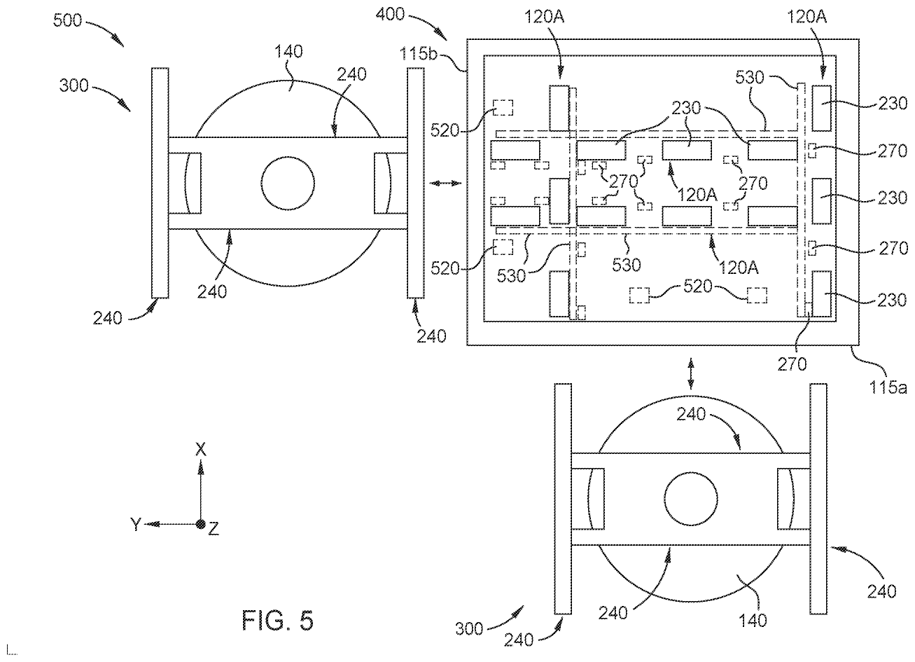

FIG. 5 illustrates a top view of a system 500 that includes the example carrier 300 of FIG. 3 and the example routing chamber 400 of FIG. 4, in accordance with embodiments of the present disclosure. FIG. 6 illustrates a side view of the example routing chamber 400 of FIG. 4, in accordance with embodiments of the present disclosure. For ease of description, FIGS. 5 and 6, which both illustrate the example routing chamber 400 of FIG. 4, are described together.

In some embodiments, and as illustrated in FIGS. 5 and 6, the routing chamber 400 may include two magnetic levitation actuator assemblies 120A disposed in the X-direction, and two magnetic levitation actuator assemblies 120A disposed in the Y-direction. Each of the one or more magnetic levitation actuator assemblies 120A may include a plurality of linear stators (e.g., linear stators 230). For example, each of the magnetic levitation actuator assemblies 120A disposed in the X-direction may include three linear stators 230, and each of the two magnetic levitation actuator assemblies 120A disposed in the Y-direction may each include four linear stators 230, for a total of 14 linear stators 230 in the routing chamber.

The routing chamber 400 may be configured to change the axial direction of travel of the carrier 300 so that carrier 300 moves in a linear fashion in a first axial direction (e.g., X-direction) instead of linearly in a second axial direction (e.g., Y-direction), or vice versa. The axial direction of travel of the carrier 300 may be configured to be changed without moving the one or more magnetic levitation actuator assemblies 120A. For example, the routing chamber 400 may receive the carrier 300 through a port (e.g., second port 412 in FIG. 4) in the second sidewall 115b, and selectively change the direction of axial travel of the carrier 300 to enable the carrier 300 to exit the routing chamber 400 through another port (e.g., first port 411 in FIG. 4) in the first sidewall 115a. In this manner, the routing chamber 400 may facilitate the transportation of the carrier 300 from one chamber arranged in a first direction (e.g., the fourth station 114, arranged in the X-direction) to another chamber arranged in a second direction (e.g., the sixth station 116, arranged in the Y-direction), as described above. While inside the routing chamber 400, the carrier 300 may be configured to be disposed in the body 410 below the lid assembly 420, as illustrated.

The routing chamber 400 may include a plurality of top sensors (e.g., top sensors 270). The top sensors 270 may be disposed between or adjacent to the linear stators 230 of the magnetic levitation actuator assemblies 120A. As illustrated in FIGS. 5 and 6, the top sensors 270 may be aligned parallel to the magnetic levitation actuator assemblies 120A disposed in the X-direction and to the magnetic levitation actuator assemblies 120A disposed in the Y-direction. Although the routing chamber 400 in FIG. 5 is illustrated as having six top sensors 270 disposed in the X-direction and ten sensors disposed in the Y-direction, any number of top sensors 270 may be used. The top sensors 270 may be disposed in a plurality of openings 720 in the housing 425, and may be supported by the housing 425, and the membrane 430 may include a plurality of recesses 750 configured to receive the top sensors 270. As such, the housing 425 may be configured to support the weight of the top sensors 270 without the help of the membrane 430. As described above, the top sensors 270 may be included in a top of the routing chamber 400, and may also, in some embodiments, the top sensors 270 may also be included in a bottom of the routing chamber.

The top sensors 270 may be implemented as magnetic sensors, and may be configured to measure and/or or detect the presence of and/or a position of the carrier 300 during contactless levitation and/or transportation, as described above. In some cases, the top sensors 270 may be configured to measure and/or or detect the levitation of the carrier 300, and may be referred to as levitation sensors. For example, the top sensors 270 may be configured to measure the position of the carrier 300 in the Z-direction.

The routing chamber 400 may include one or more landing features 610 (e.g., a landing rail), as illustrated in FIG. 6. The one or more landing features 610 may be disposed in the X-direction and/or the Y-direction to enable transportation of the carrier 300 in one or both of the X-direction and the Y-direction. In some embodiments, the routing chamber 400 may include four landing features 610, and the four landing features 610 may be disposed in each of the areas 530 illustrated in FIG. 5 (e.g., two may be disposed in the X-direction and two may be disposed in the Y-direction). The array of legs 320 of the carrier 300 may be configured to contact the landing feature 610 and support the carrier 300 when the carrier 300 is not being levitated. For example, when levitation of the carrier 300 fails (e.g., power is lost), the carrier 300 may fall, and the legs 320 may land on one of the landing features 610. In some embodiments, the legs 320 may be configured to keep the carrier 300A upright.

The routing chamber 400 may include a plurality of bottom sensors 620, as illustrated in FIG. 6. In some cases, the bottom sensors 620 may be coupled to a bottom of the body 410 and disposed under one or more of the magnetic levitation actuator assemblies 120A (e.g., in one or more of the areas 530 illustrated in FIG. 5). For example, one or more of the plurality of bottom sensors 620 may be included in one or more of the landing features 610 or located underneath one or more of the landing features 610. The plurality of bottom sensors 620 may be configured to measure and/or or detect the position of the carrier 300 along the X-axis and/or the yaw of the carrier 300 about the Z-axis, as illustrated in FIG. 6, and may be referred to as drive sensors. In some embodiments, the plurality of bottom sensors 620 may include a single bottom sensor 620 disposed in the X-direction (e.g., under a landing feature 610 disposed in the X-direction), and a single bottom sensor 620 disposed in the Y-direction (e.g., under a landing feature 610 disposed in the Y-direction). For example, one of the bottom sensors 620 may be coupled to a bottom of the body 410 and disposed in one of the areas 530 aligned in the X-direction, and one of the bottom sensors 620 may be coupled to the bottom of the body 410 and disposed in one of the areas 530 aligned in the Y-direction. In some embodiments, the bottom sensors 620 may be isolated from the body 410.

The routing chamber 400 may include one or more side sensors 630, as illustrated in FIG. 6. The one or more side sensors 630 may be located on a side of the body 410, and/or located in the lid assembly 420. The one or more side sensors 630 may be configured to measure and/or detect the position of the carrier 300 in the Y-direction. In some embodiments, the one or more magnetic levitation actuator assemblies 120A may further include a magnetic actuator 640 configured to interact with material included in the carrier 300 and adjust the position of the carrier 300 in the Y-direction, based on information from the one or more side sensors 630. For example, the magnetic actuator 640 may be configured to interact the magnetic levitation element 240 and/or the features 250 thereof, and the magnetic actuator 640 may be used to move the carrier 300 to align the center of the object 140 (and the carrier 300) with the center of the routing chamber 400. The one or more side sensors 630 may be isolated from the body 410, as illustrated.

The routing chamber 400 may include a plurality of optical sensors 520 (e.g., optical three-dimensional sensors). Although the routing chamber 400 in FIG. 5 is illustrated as having four optical sensors 520, any number of optical sensors 520 may be used. One or more of the optical sensors 520 may be coupled to the lid assembly 420, and one or more of the optical sensors 520 may be coupled to a bottom of the body 410. In this manner, the optical sensors 520 may be configured to find a center of the object 140 transported by the carrier 300, and may be referred to as local center finding sensors. In some cases, the optical sensors 520 may be used to help to find the position of the carrier 300, such as the center of the carrier. For example, the optical sensors 520 may measure and/or detect multiple points of the object 140 and determine the position of the carrier 300. The magnetic actuator 640 may be configured to interact with material included in the carrier 300 and adjust the position of the carrier 300 in the Y-direction, based on information from the optical sensors 520. For example, the magnetic actuator 640 may be configured to interact with the magnetic levitation element 240 and/or the features 250 thereof, and the magnetic actuator 640 may be used to move the carrier 300 to align the center of the object 140 (and the carrier 300) with the center of the routing chamber 400.

In some embodiments, one or more of the optical sensors 520 may be included in the housing 425, and the membrane 430 may include a plurality of recesses (e.g., recesses 750) configured to receive the optical sensors 520. In some embodiments, one or more of the optical sensors 520 may be included in another station of the substrate processing system 100. For example, the plurality of optical sensors 520 may include two optical sensors 520, and one of the optical sensors 520 may be included in the routing station 115 (implemented as the routing chamber 400), and the other of the optical sensors 520 may be included in the processing station 116. In another example, the plurality of optical sensors 520 may include two optical sensors 520, and one of the optical sensors 520 may be included in the routing station 115 (implemented as the routing chamber 400), and the other of the optical sensors 520 may be included in the station 114. The one or more of the optical sensors 520 may be isolated from the body 410, as illustrated.

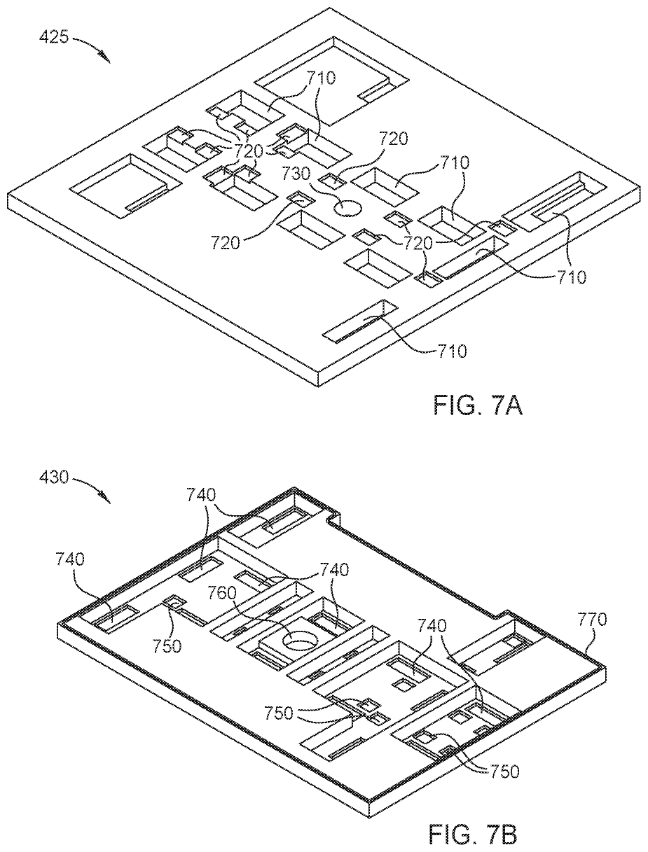

FIG. 7A illustrates the housing 425 of a lid assembly 420 of the example routing chamber 400 of FIG. 4, in accordance with embodiments of the present disclosure.

As described above, the housing 425 may include openings 710 to house and/or support the one or more magnetic levitation actuator assemblies 120A (not illustrated), and the openings 720 to house and/or support the plurality of top sensors 270. In some embodiments, the housing 425 may be machine formed. The housing 425 may also include a terminal plate (not shown) that houses the communication, power, sensor, water, and gas line connections between the routing chamber 400 and the outside world. The housing 425 may include an opening 730 that may be configured to be connected to a gas diffuser for the routing chamber 400 gas purge port in order to purge gasses from the routing chamber 400. The opening 730 may also be used to mount a non-contact measurement device configured to determine the presence of and a position of the object 140 on the carrier 300, the presence of and a position of the carrier 300, and/or other properties of the object 140 (e.g., object thickness, temperature, warpage, optical properties, and the like). The opening 730 may also be used for venting in conjunction with the opening 330 of the carrier 300.

FIG. 7B illustrates the membrane 430 of a lid assembly 420 of the example routing chamber 400 of FIG. 4, in accordance with embodiments of the present disclosure.

As described above, the membrane 430 may include the plurality of recesses 740 configured to receive the one or more magnetic levitation actuator assemblies 120A, and the plurality of recesses 750 configured to receive the top sensors 270, as illustrated in FIG. 7B. The membrane 430 may include an opening 760 (which may be configured to align with the opening 730 when the membrane 430 and the housing 425 are coupled together).

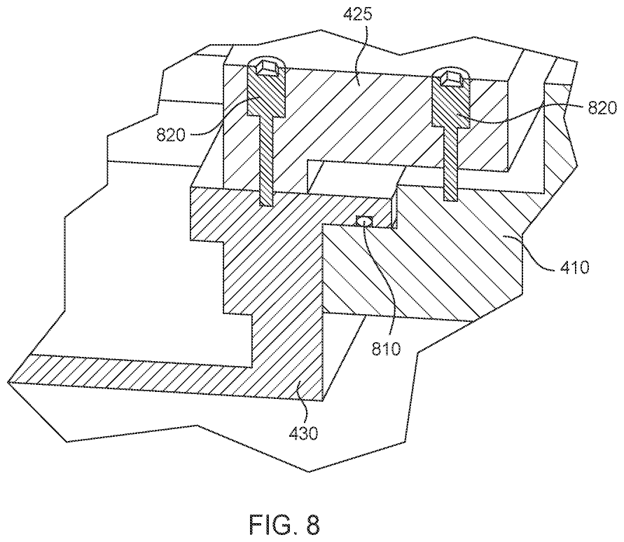

FIG. 8 illustrates a view of an example connection between the housing 425 and the membrane 430 of the lid assembly 420 of the example routing chamber 400 of FIG. 4, in accordance with embodiments of the present disclosure.

In some embodiments, the membrane 430 may be coupled to the body 410 using one or more O-rings 810 and one or more mounting features 820 (e.g., bolts), as illustrated in FIG. 8. In these embodiments, the housing 425 may be coupled to the membrane 430 using one or more mounting features 820 (e.g., bolts), also as illustrated in FIG. 8. In this manner, the coupling between the membrane 430, the housing 425, and the body 410 may seal and isolate the interior of the body 410 from the outside world. In other embodiments (not illustrated), the membrane 430 may be sealed to the housing 425 and the body 410 using two or more O-rings (e.g., O-ring 770) configured to couple the membrane 430 to the housing 425 and the body 410, such that the interior of the body 410 is sealed and isolated from the outside world.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

While the foregoing is directed to embodiments of the present disclosure, other and further embodiments of the disclosure may be devised without departing from the basic scope thereof, and the scope thereof is determined by the claims that follow.

What is claimed is:

1. A chamber comprising:
a body; and
a lid assembly configured to be coupled to a top of the body, the lid assembly comprising:
a housing comprising a first magnetic levitation actuator assembly aligned in a first direction, a second magnetic levitation actuator assembly aligned in a second direction, and a plurality of top sensors, wherein the first direction is different than the second direction; and
a membrane configured to be coupled to the housing, the membrane including a plurality of recesses configured to receive the first magnetic levitation actuator assembly, the second magnetic levitation actuator assembly, and the plurality of top sensors.

2. The chamber of claim 1, wherein the housing further comprises a third magnetic levitation actuator assembly aligned in the first direction and a fourth magnetic levitation actuator assembly aligned in the second direction.

3. The chamber of claim 1, wherein the first magnetic levitation actuator assembly comprises two or more linear stators, wherein the second magnetic levitation actuator assembly comprises two or more linear stators, and wherein each linear stator comprises an array of features.

4. The chamber of claim 3, wherein a first sensor of the plurality of top sensors is disposed between two linear stators of the two or more linear stators of the first magnetic levitation actuator assembly, and wherein a second sensor of the plurality of top sensors is disposed between two linear stators of the two or more linear stators of the second magnetic levitation actuator assembly.

5. The chamber of claim 1, wherein the housing comprises a first metal and the membrane comprises a second metal different than the first metal.

6. The chamber of claim 5, wherein the first metal comprises aluminum and the second metal comprises stainless steel.

7. The chamber of claim 1, further comprising:
a first port included in a first sidewall of the body, the first port configured to accept a carrier; and
a second port included in a second sidewall of the body, the second port configured to accept the carrier, and wherein the chamber is configured such that the carrier is disposed below the lid assembly when the carrier is inside the body.

8. The chamber of claim 7, wherein the first sidewall is adjacent to and perpendicular to the second sidewall.

9. The chamber of claim 2, further comprising:
a first bottom sensor coupled to a bottom of the body and disposed under the first magnetic levitation actuator assembly or the third magnetic levitation actuator assembly; and
a second bottom sensor coupled to the bottom of the body and disposed under the second magnetic levitation actuator assembly or the fourth magnetic levitation actuator assembly.

10. The chamber of claim 1, wherein the plurality of top sensors comprise magnetic sensors.

11. The chamber of claim 1, wherein the housing and the membrane are removable from the chamber, and wherein the housing is removable from the membrane.

12. The chamber of claim 1, further comprising:
a first landing feature coupled to a bottom of the body and aligned in the first direction; and
a second landing feature coupled to the bottom of the body and aligned in the second direction.

13. The chamber of claim 1, further comprising a first optical sensor coupled to the lid assembly and a second optical sensor coupled to a bottom of the body.

14. The chamber of claim 1, further comprising one or more side sensors coupled to a sidewall of the body.

15. A chamber comprising:
a body; and
a lid assembly configured to be coupled to a top of the body, the lid assembly comprising:
a housing comprising a first magnetic levitation actuator assembly aligned in a first direction, a second magnetic levitation actuator assembly aligned in a second direction, a third magnetic levitation actuator assembly aligned in the first direction, a fourth magnetic levitation actuator assembly aligned in the second direction, and a plurality of top sensors, wherein the first direction is different than the second direction; and
a membrane configured to be coupled to the housing, the membrane including a plurality of recesses configured to receive the first magnetic levitation actuator assembly, the second magnetic levitation actuator assembly, the third magnetic levitation actuator assembly, the fourth magnetic levitation actuator assembly, and the plurality of top sensors, and wherein the housing comprises a first metal and the membrane comprises a second metal different than the first metal.

16. The chamber of claim 15, wherein the first magnetic levitation actuator assembly comprises two or more linear stators, wherein the second magnetic levitation actuator assembly comprises two or more linear stators, wherein the third magnetic levitation actuator assembly comprises two or more linear stators, wherein the fourth magnetic levitation actuator assembly comprises two or more linear stators, and wherein each linear stator comprises an array of features.

17. The chamber of claim 15, wherein the first metal comprises aluminum and the second metal comprises stainless steel.

18. The chamber of claim 15, further comprising:
a first port included in a first sidewall of the body, the first port configured to accept a carrier; and
a second port included in a second sidewall of the body, the second port configured to accept the carrier, and wherein the chamber is configured such that the carrier is disposed below the lid assembly.

19. The chamber of claim 15, wherein the housing and the membrane are removable from the chamber, and wherein the housing is removable from the membrane.

20. A chamber comprising:
a body; and
a lid assembly configured to be coupled to a top of the body, the lid assembly comprising:
a housing comprising a first magnetic levitation actuator assembly aligned in a first direction, a second magnetic levitation actuator assembly aligned in a second direction, a third magnetic levitation actuator assembly aligned in the first direction, a fourth magnetic levitation actuator assembly aligned in the second direction, and a plurality of top sensors, wherein the first direction is different than the second direction, wherein the first magnetic levitation actuator assembly and the third magnetic levitation actuator assembly each comprise four linear stators, and wherein the second magnetic levitation actuator assembly and the fourth magnetic levitation actuator assembly each comprise three linear stators; and
a membrane configured to be coupled to the housing, the membrane including a plurality of recesses configured to receive the first magnetic levitation actuator assembly, the second magnetic levitation actuator assembly, the third magnetic levitation actuator assembly, the fourth magnetic levitation actuator assembly, and the plurality of top sensors, and wherein the housing comprises aluminum and the membrane comprises stainless steel.
